(19) United States
(12) Patent Application Publication
(10) Pub. No.: US 2013/0341765 A1
(43) Pub. Date: Dec. 26, 2013

(54) SEMICONDUCTOR DEVICE AND METHOD FOR MANUFACTURING SEMICONDUCTOR DEVICE

(71) Applicant: FUJITSU LIMITED, Kawasaki-shi (JP)

(72) Inventor: Tomoyuki AKAHOSHI, Atsugi (JP)

(73) Assignee: Fujitsu Limited, Kawasaki-shi (JP)

(21) Appl. No.: 13/869,306

(22) Filed: Apr. 24, 2013

(30) Foreign Application Priority Data
Jun. 20, 2012 (JP) 2012-138562

(51) Int. Cl. H01L 23/544; H01L 21/56; H01L 23/538

(52) U.S. Cl. CPC H01L 23/544; H01L 23/5384; H01L 21/56
USPC 257/621; 438/127

(57) ABSTRACT

A semiconductor device includes: a semiconductor substrate; a plurality of metal terminals that are formed on a surface of the semiconductor substrate on the opposite side to a circuit-forming surface; and a resin that is formed on the surface of the semiconductor substrate on the opposite side to the circuit-forming surface, and covers at least part of side surfaces of the metal terminals, wherein upper surfaces of the metal terminals are exposed from the resin.

### CROSS-REFERENCE TO RELATED APPLICATION

This application is based upon and claims the benefit of priority from the prior Japanese Patent Application No. 2012-138562 filed on Jun. 20, 2012, the entire contents of which are incorporated herein by reference.

### FIELD

The embodiments discussed herein are related to a semiconductor device and a method for manufacturing a semiconductor device.

### BACKGROUND

In recent years, technological development to miniaturize and increase the size of integrated circuits in semiconductor devices such as semiconductor chips and LSI chips for central processing units (CPUs) and application-specific integrated circuits (ASICs) has been achieved together with the development of computers and communication equipment. The development of stacked package configurations is widely carried out as an alternative approach to the development of individual semiconductor device units. In the stacked package configurations, a plurality of semiconductor devices are stacked in a three-dimensional manner to realize the same functions as when an integrated circuit is increased in scale.

Electrical connection between a plurality of stacked semiconductor devices is implemented using a through-silicon via (TSV). A plurality of methods referred to as “via first”, “via middle”, and “via last” based on the process sequence in which integrated circuits and through-silicon vias are formed have been proposed as methods for manufacturing a semiconductor device having through-silicon vias. Furthermore, in the process of manufacturing a semiconductor device, there is an option as to whether or not a redistribution layer is to be formed on the rear surface of a semiconductor substrate of the semiconductor device. In the case where a redistribution layer is not formed on the rear surface of the semiconductor substrate, part of the through-silicon via is exposed at the rear surface of the semiconductor substrate, and the exposed through-silicon via is used as a connection terminal between a plurality of semiconductor devices.

In a method for manufacturing a semiconductor-device stacked package, positioning is carried out for a plurality of semiconductor devices to be stacked. In the case where a wiring layer is formed on a circuit-forming surface of a semiconductor device, an alignment mark or an identification mark for positioning is formed by the wiring layer on the circuit-forming surface of the semiconductor device. In addition, there is a technique in which a through-silicon via formed in the rear surface of a chip serves as an alignment mark.

The following is reference documents:

[Document 1] Japanese Laid-open Patent Publication No. 2005-217071,

[Document 2] Japanese Laid-open Patent Publication No. 2010-147230,

[Document 3] Japanese Laid-open Patent Publication No. 10-303364, and

[Document 4] Japanese Laid-open Patent Publication No. 2002-118055.

### SUMMARY

According to an aspect of the invention, a semiconductor device includes: a semiconductor substrate; a plurality of metal terminals that are formed on a surface of the semiconductor substrate on the opposite side to a circuit-forming surface; and a resin that is formed on the surface of the semiconductor substrate on the opposite side to the circuit-forming surface, and covers at least part of side surfaces of the metal terminals, wherein upper surfaces of the metal terminals are exposed from the resin.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a cross-sectional view of a semiconductor chip according to embodiment 1;

FIG. 2 is a partial enlarged view of the rear surface of the semiconductor chip (semiconductor wafer) according to embodiment 1;

FIG. 3 is a partial enlarged view of the rear surface of the semiconductor chip (semiconductor wafer) according to embodiment 1;

FIG. 4 is a partial enlarged view of the rear surface of the semiconductor chip (semiconductor wafer) according to embodiment 1;

FIG. 5 is a partial enlarged view of the rear surface of the semiconductor chip (semiconductor wafer) according to embodiment 1;

FIGS. 6A to 6C illustrate a method for manufacturing a semiconductor device according to embodiment 1;

FIGS. 7A and 7B illustrate the method for manufacturing a semiconductor device according to embodiment 1;

FIG. 8 illustrates the method for manufacturing a semiconductor device according to embodiment 1;

FIG. 9 illustrates a first example of a method for stacking semiconductor devices;

FIG. 10 illustrates the first example of a method for stacking semiconductor devices;

FIG. 11 illustrates the first example of a method for stacking semiconductor devices;

FIG. 12 illustrates the first example of a method for stacking semiconductor devices;

FIG. 13 illustrates the first example of a method for stacking semiconductor devices;

FIG. 14 illustrates a second example of a method for stacking semiconductor devices;

FIG. 15 illustrates the second example of a method for stacking semiconductor devices;

FIG. 16 illustrates the second example of a method for stacking semiconductor devices;

FIG. 17 illustrates the second example of a method for stacking semiconductor devices;

FIG. 18 is a cross-sectional view of a semiconductor chip according to embodiment 2;

FIGS. 19A to 19C illustrate a method for manufacturing a semiconductor device according to embodiment 2; and

FIG. 20 illustrates the method for manufacturing a semiconductor device according to embodiment 2.

### DESCRIPTION OF EMBODIMENTS

A semiconductor device and a method for manufacturing a semiconductor device according to the embodiments are described hereafter with reference to the drawings. The configurations of the following embodiments are exemplifications, and the semiconductor device and method for manufacturing a semiconductor device according to the embodiments are not restricted to the configurations of the embodiments described below.

### Embodiment 1

A first embodiment (embodiment 1) of a semiconductor device and a method for manufacturing a semiconductor device according to the embodiment are described.

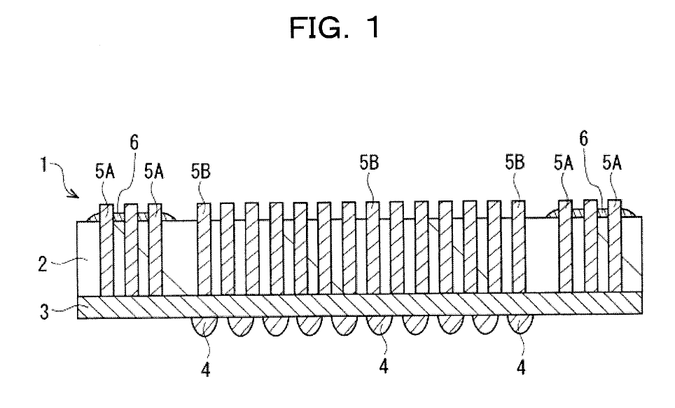

As depicted in FIG. 1, a semiconductor chip (LSI chip) 1 includes a semiconductor wafer (semiconductor substrate) 2, a wiring layer 3, connection terminals 4, metal terminals 5A and 5B, and resin 6. FIG. 1 is a cross-sectional view of the semiconductor chip 1 according to embodiment 1. The semiconductor chip 1 is an example of a semiconductor device. The semiconductor wafer 2 is, for example, a silicon wafer.

An integrated circuit is formed on one surface of the semiconductor chip 1. The integrated circuit of the semiconductor chip 1 has: an element such as a transistor which is formed on one surface of the semiconductor wafer 2 by a transistor-forming process (front end of the line; FEOL); and the wiring layer 3 which is formed by a wiring-forming process (back end of the line; BEOL). The wiring layer 3 has metal wiring, an insulation layer, and a plug, which are not depicted. The metal wiring includes a ground (GND) wire, power supply wire, and signal wire. Hereafter, the surface (circuit-forming surface) of the semiconductor chip 1 on which the integrated circuit is formed is referred to as the front surface of the semiconductor chip 1. Furthermore, the surface (circuit-forming surface) of the semiconductor wafer 2 on which the integrated circuit is formed is referred to as the front surface of the semiconductor wafer 2.

An alignment mark (identification mark) is formed by the metal terminals 5A and resin 6 on the surface of the semiconductor chip 1 on the opposite side to the circuit-forming surface (hereafter referred to as the rear surface of the semiconductor chip 1). In other words, the alignment mark formed on the rear surface of the semiconductor chip 1 includes the metal terminals 5A and resin 6. The metal terminals 5A are metal terminals used for an alignment mark (identification mark), and the metal terminals 5B are metal terminals used for connection. The metal terminals 5A and 5B are formed within the semiconductor wafer 2 and pass through the semiconductor wafer 2. One end of the metal terminals 5A and 5B protrudes from the rear surface of the semiconductor wafer 2. The rear surface of the semiconductor wafer 2 is the surface of the semiconductor wafer 2 on the opposite side to the circuit-forming surface. The other end of the metal terminals 5A and 5B is in contact with the wiring layer 3.

The metal terminals 5A may be electrically connected with the metal wiring and plug of the wiring layer 3. If the metal terminals 5A are electrically connected with the ground wire of the wiring layer 3, part of the alignment mark has the same potential as ground, and noise during operation of the semiconductor chip 1 may be reduced. The metal terminals 5A may not be electrically connected with the metal wiring and plug of the wiring layer 3. Some of the plurality of metal terminals 5A may be electrically connected with the metal wiring and plug of the wiring layer 3, and some of the plurality of metal terminals 5A may not be electrically connected with the metal wiring and plug of the wiring layer 3. The metal terminals 5B are electrically connected with the metal wiring and plug of the wiring layer 3 and are also electrically connected with the connection terminals 4. The metal terminals 5A and 5B are, for example, copper (Cu), tungsten (W), or the like. The connection terminals 4 are, for example, tin-silver (SnAg) solder, gold (Au), copper (Cu), or the like.

The resin 6 is, for example, a thermosetting polyimide resin, thermosetting epoxy resin, photosensitive polyimide resin, photosensitive epoxy resin, or an electrically conductive resin. The electrically conductive resin is a resin which is electrically conductive and may be a thermosetting electrically conductive paste or a photosensitive electrically conductive paste. The photosensitive electrically conductive paste may be a photosensitive silver paste. If the resin 6 is an electrically conductive resin, the plurality of metal terminals 5A are electrically connected by the resin 6. If the metal terminals 5A are electrically connected with the ground wire of the wiring layer 3, the whole of the alignment mark has the same potential as ground, and noise during operation of the semiconductor chip 1 may be further reduced. Furthermore, resin having poor wettability with the metal terminals 5A may be used as the resin 6.

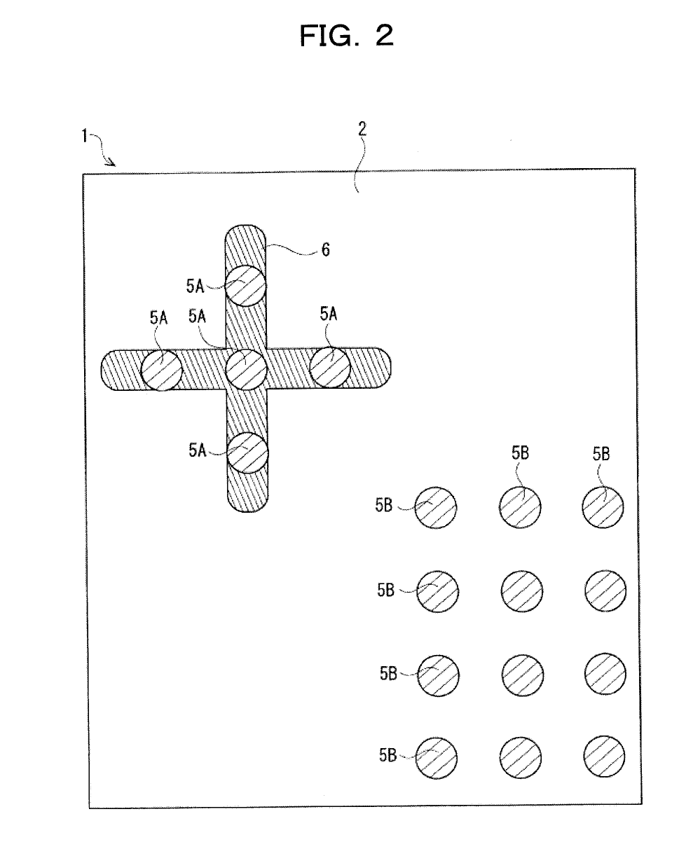

FIGS. 2 to 5 are partial enlarged views of the rear surface of the semiconductor chip 1 (semiconductor wafer 2) according to embodiment 1. In the examples depicted in FIGS. 2 to 5, the alignment mark formed by the metal terminals 5A and resin 6 is cross-shaped.

In the example depicted in FIG. 2, the plurality of metal terminals 5A are arranged in the shape of a cross with a certain distance therebetween. The resin 6 is formed so as to cover part of the side surfaces of the metal terminals 5A. The upper surfaces of the metal terminals 5A are exposed from the resin 6. Part of the side surfaces of the metal terminals 5A is exposed from the resin 6. Adjacent metal terminals 5A are connected via the resin 6.

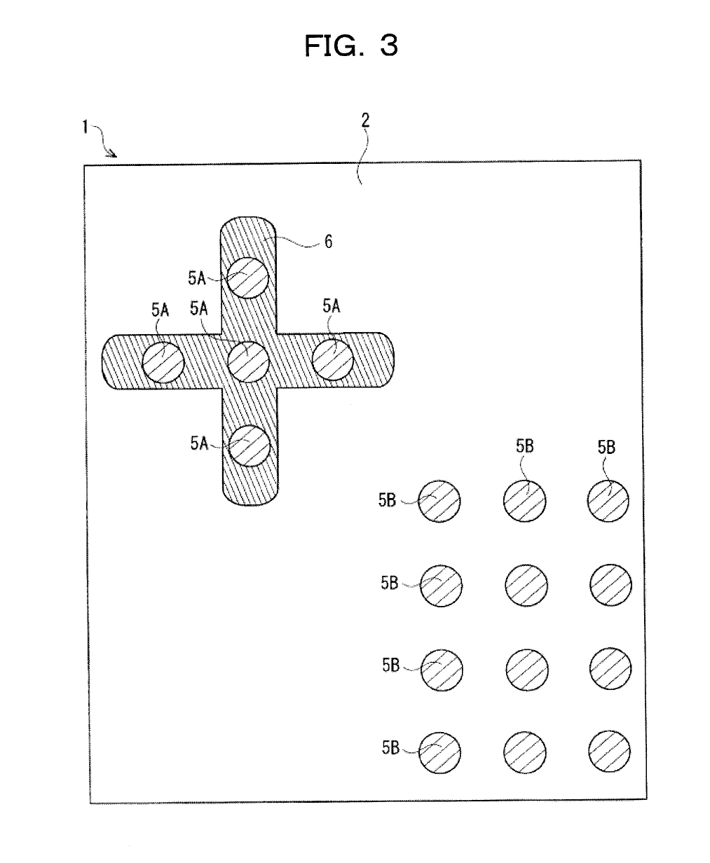

In the example depicted in FIG. 3, the plurality of metal terminals 5A are arranged in the shape of a cross with a certain distance therebetween. The resin 6 is formed so as to cover the side surfaces of the metal terminals 5A, with the resin 6 being formed so as to completely surround the side surfaces of the metal terminals 5A. The upper surfaces of the metal terminals 5A are exposed from the resin 6. Adjacent metal terminals 5A are connected via the resin 6.

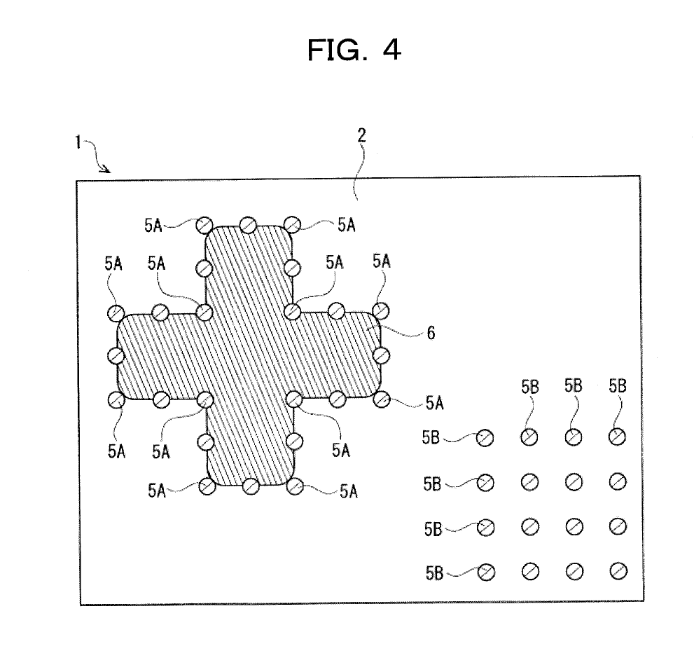

In the example depicted in FIG. 4, the plurality of metal terminals 5A are arranged in the shape of a cross with a certain distance therebetween. The resin 6 is formed so as to cover part of the side surfaces of the metal terminals 5A. The upper surfaces of the metal terminals 5A are exposed from the resin 6. Part of the side surfaces of the plurality of metal terminals 5A is exposed from the resin 6. The resin 6 is formed within a region surrounded by the plurality of metal terminals 5A. The resin 6 may be formed within the region surrounded by the plurality of metal terminals 5A, by dripping the resin 6 in the region surrounded by the plurality of metal terminals 5A. The plurality of metal terminals 5A are connected via the resin 6. The surface area of the resin 6 and the area of the region surrounded by the plurality of metal terminals 5A are equal to each other. In other words, the resin 6 does not protrude from the region surrounded by the plurality of metal terminals 5A.

The resin 6 is formed within the region surrounded by the plurality of metal terminals 5A by controlling the amount of the resin 6 that is dripped in the region surrounded by the plurality of metal terminals 5A. Furthermore, the plurality of metal terminals 5A restrict the wet-spreading of the resin 6, and the resin 6 is thereby formed within the region surrounded by the plurality of metal terminals 5A. As depicted in FIG. 4, it is possible to form an alignment mark having neat edges, by forming the resin 6 within the region surrounded by the plurality of metal terminals 5A.

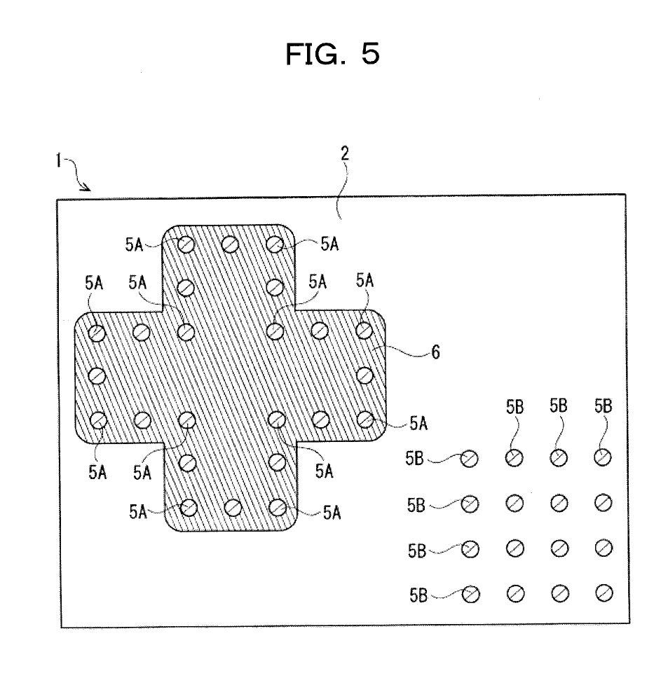

In the example depicted in FIG. 5, the plurality of metal terminals 5A are arranged in the shape of a cross with a certain distance therebetween. The resin 6 is formed so as to cover the side surfaces of the plurality of metal terminals 5A, with the resin 6 being formed so as to completely surround the side surfaces of the metal terminals 5A. The upper surfaces of the plurality of metal terminals 5A are exposed from the resin 6. The resin 6 is formed within the region surrounded by the plurality of metal terminals 5A, and the resin 6 is also formed around the periphery of the region surrounded by the plurality of metal terminals 5A. The resin 6 may be formed in the region surrounded by the plurality of metal terminals 5A, by dripping the resin 6 in the region surrounded by the plurality of metal terminals 5A. In the example depicted in FIG. 5, the amount of the resin 6 that is dripped is greater than in the example depicted in FIG. 4, and it is therefore possible to form the resin 6 around the periphery of the region surrounded by the plurality of metal terminals 5A. The plurality of metal terminals 5A are connected via the resin 6. The surface area of the resin 6 is greater than the area of the region surrounded by the plurality of metal terminals 5A. In other words, the resin 6 protrudes from the region surrounded by the plurality of metal terminals 5A.

FIGS. 2 to 5 depict examples in which the alignment mark formed by the metal terminals 5A and resin 6 is cross-shaped. The embodiment is not restricted to the examples depicted in FIGS. 2 to 5, and the alignment mark formed by the metal terminals 5A and resin 6 may have another shape such as an “L” shape.

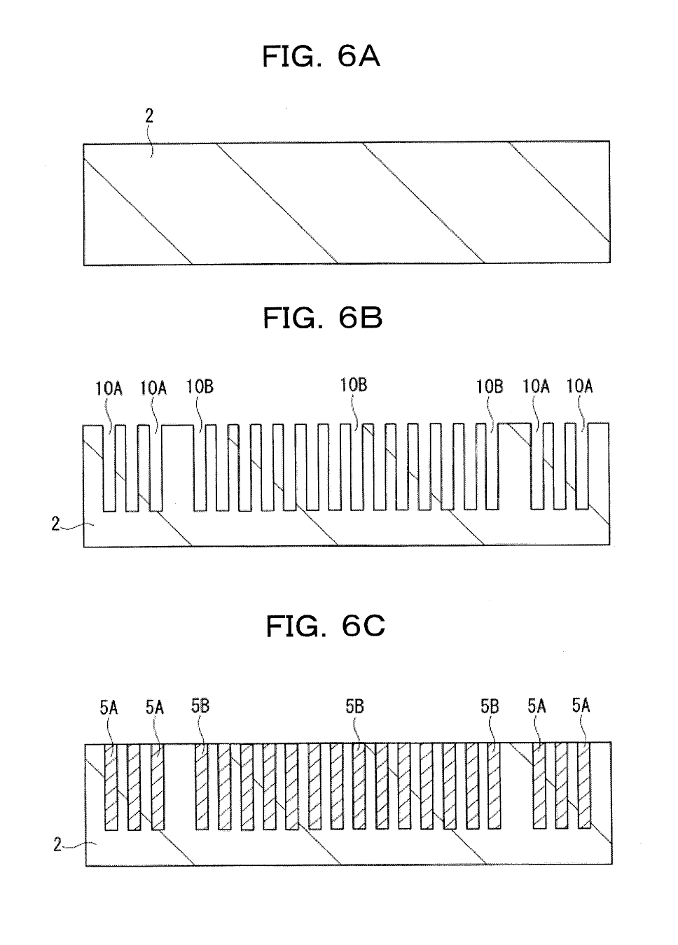

The method for manufacturing a semiconductor device according to embodiment 1 is described with reference to FIGS. 6A to 8. First, a semiconductor wafer 2 is prepared as depicted in FIG. 6A. An element such as a transistor is formed on the front surface of the semiconductor wafer 2 by a transistor-forming process. The semiconductor wafer 2 is at the stage prior to being divided into individual pieces, and FIGS. 6A to 8 depict part of the semiconductor wafer 2.

Next, a resist liquid is applied to the front surface of the semiconductor wafer 2, and a resist pattern (not depicted) is formed on the front surface of the semiconductor wafer 2 by photolithography. Next, dry-etching using the Bosch process is carried out from the front surface of the semiconductor wafer 2 to the rear surface of the semiconductor wafer 2 with the resist pattern serving as a mask, and a plurality of vias 10A and 10B are formed in the semiconductor wafer 2 as depicted in FIG. 6B. After the plurality of vias 10A and 10B are formed in the semiconductor wafer 2, the resist pattern is removed by ashing.

The dry-etching using the Bosch process employs, for example, an SF₆ gas to etch the semiconductor wafer 2, and an O₂ gas to form a sidewall insulation layer (not depicted) on the side surfaces of the vias 10A and 10B. The sidewall insulation layer is, for example, a SiO₂ layer. Here, embodiment 1 describes an example in which the plurality of vias 10A and 10B are formed by dry-etching using the Bosch process. However, the embodiment is not restricted to the Bosch process, and the plurality of vias 10A and 10B may be formed in the semiconductor wafer 2 by reactive-ion etching (RIE).

The vias 10B are formed corresponding to the positions of the connection terminals of another semiconductor chip to be stacked on top of the semiconductor wafer 2, and the vias 10A are formed in positions unrelated to the positions of the connection terminals of the other semiconductor chip to be stacked on top of the semiconductor wafer 2. In addition, the forming positions of the vias 10A are preferably near the ends of semiconductor chips 1 that are formed into individual pieces by a subsequent dicing process.

Next, after a resist pattern (not depicted) is formed on the front surface of the semiconductor wafer 2 by photolithography, metal fills inside the vias 10A and 10B by plating to thereby form a plurality of metal terminals 5A and 5B inside the semiconductor wafer 2, as depicted in FIG. 6C. For example, titanium (Ti) and copper (Cu) are deposited by sputtering so as to cover the sidewall insulation layer formed within the vias 10A and 10B, and copper (Cu) is plated by electroplating to thereby fill the inside of the vias 10A and 10B with metal. Here, an example using copper (Cu) is described, but tungsten (W) may be used instead of copper (Cu). After the metal terminals 5A and 5B have been formed within the semiconductor wafer 2, the resist pattern is removed by ashing.

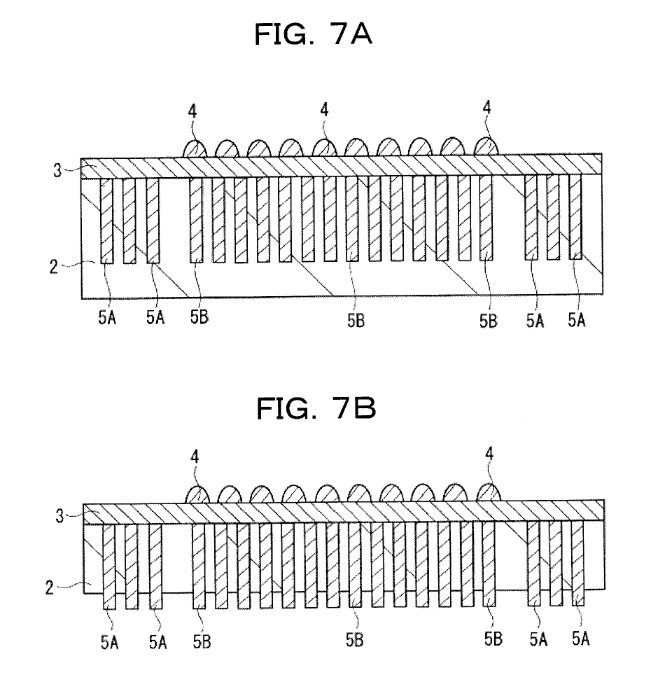

Next, after the front surface of the semiconductor wafer 2 has been planarized by chemical mechanical polishing (CMP), a wiring layer 3 is formed on the front surface of the semiconductor wafer 2 and connection terminals 4 are formed on the wiring layer 3, as depicted in FIG. 7A.

Next, by backgrinding from the rear surface of the semiconductor wafer 2, the rear surface of the semiconductor wafer 2 is ground to thereby reduce the thickness of the semiconductor wafer 2 until the metal terminals 5A and 5B are exposed from the rear surface of the semiconductor wafer 2. The metal terminals 5A and 5B exposed from the rear surface of the semiconductor wafer 2 are also referred to as through-silicon vias (TSVs).

The plurality of metal terminals 5A exposed from the rear surface of the semiconductor wafer 2 are metal terminals used for an alignment mark. The metal terminals 5A used for an alignment mark form part of the alignment mark. The plurality of metal terminals 5B exposed from the rear surface of the semiconductor wafer 2 are metal terminals used for connection. The metal terminals 5B used for connection electrically connect a plurality of semiconductor chips 1 when the plurality of semiconductor chips 1 are stacked. Furthermore, the metal terminals 5B used as metal terminals for connection electrically connect a semiconductor chip 1 to another semiconductor chip when the semiconductor chip 1 and the other semiconductor chip are stacked.

Next, wet-etching or dry-etching is carried out on the rear surface of the semiconductor wafer 2 to selectively etch only the semiconductor wafer 2, and the metal terminals 5A and 5B are thereby made to protrude from the rear surface of the semiconductor wafer 2 as depicted in FIG. 7B. For example, wet-etching may be carried out using hydrofluoric acid (HF). A sidewall insulation layer is formed on the upper surfaces and side surfaces of the metal terminals 5A and 5B protruding from the rear surface of the semiconductor wafer 2. The sidewall insulation layer formed on the upper surfaces and side surfaces of the metal terminals 5A and 5B protruding from the rear surface of the semiconductor wafer 2 may be removed by carrying out wet-etching using hydrofluoric acid (HF). In addition, if the sidewall insulation layer formed on the upper surfaces of the metal terminals 5A and 5B is removed by carrying out wet-etching or dry-etching on the rear surface of the semiconductor wafer 2, the process for removing the sidewall insulation layer formed on the side surfaces of the metal terminals 5A and 5B may be omitted.

Next, in a state in which the rear surface of the semiconductor wafer 2 is facing upward, an ink jet control mechanism is used to position an ink jet head 20 above the position where the alignment mark is to be formed on the rear surface of the semiconductor wafer 2.

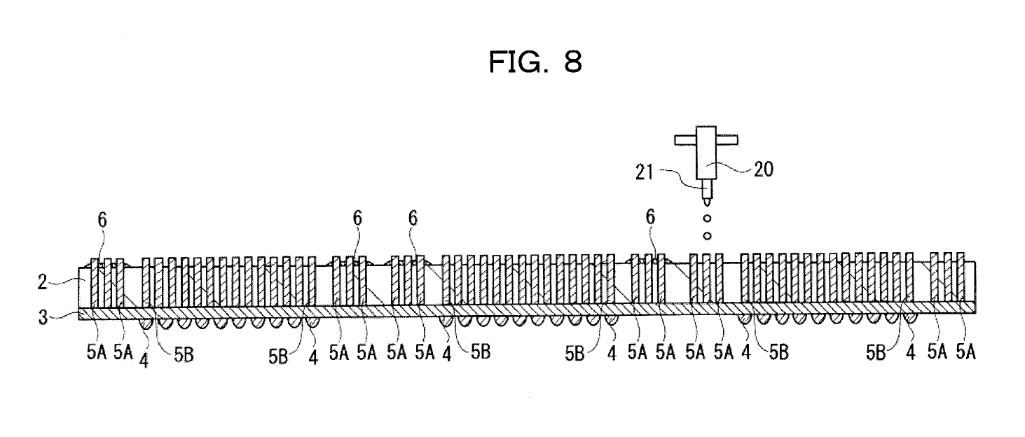

Next, as depicted in FIG. 8, resin 6 is dripped (applied) from a nozzle 21 of the ink jet head 20, and the resin 6 is thereby formed in an alignment mark-forming position on the rear surface of the semiconductor wafer 2. The amount of the resin 6 that is dripped from the nozzle 21 of the ink jet head 20 is controlled to thereby form a certain amount of the resin 6 at the alignment mark-forming position on the rear surface of the semiconductor wafer 2. By controlling the amount of the resin 6 that is dripped from the nozzle 21 of the ink jet head 20, it is possible for the upper surfaces of the metal terminals 5A protruding from the rear surface of the semiconductor wafer 2 not to be covered by the resin 6. Furthermore, by controlling the amount of the resin 6 that is dripped from the nozzle 21 of the ink jet head 20, it is possible for only part of the side surfaces of the metal terminals 5A protruding from the rear surface of the semiconductor wafer 2 to be covered by the resin 6.

If the resin 6 has poor wettability with the metal terminals 5A, it is possible to inhibit the upper surfaces of the metal terminals 5A which protrude from the rear surface of the semiconductor wafer 2 from being covered by the resin 6. That is, using the resin 6 having poor wettability with the metal terminals 5A causes the upper surfaces of the metal terminals 5A protruding from the rear surface of the semiconductor wafer 2 to be suitably exposed from the resin 6.

The metal terminals 5A are embedded in the vias 10A formed by photolithography and dry-etching. For this reason, the forming positions of the metal terminals 5A are more precise than the resin-6 dripping position implemented by the ink jet control mechanism. For example, the precision of the forming positions of the metal terminals 5A is approximately ±0.1 μm, whereas the precision of the resin-6 dripping position implemented by the ink jet control mechanism is approximately ±5 μm. Because the metal terminals 5A are provided in a position in which the alignment mark is to be formed on the rear surface of the semiconductor wafer 2, when the resin 6 is dripped on the rear surface of the semiconductor wafer 2, the resin 6 accumulates in the position in which the metal terminals 5A are formed. It is possible to form the resin 6 in a position in which the alignment mark is to be formed on the rear surface the semiconductor wafer 2, even if the precision of the resin-6 dripping position implemented by the ink jet control mechanism is low. That is, even if the resin-6 dripping position is slightly offset with respect to the position in which the alignment mark is to be formed on the rear surface of the semiconductor wafer 2. It is possible to form the resin 6 in the position in which the alignment mark is to be formed on the rear surface of the semiconductor wafer 2.

The positioning of the resin-6 dripping position implemented by the ink jet control mechanism may be carried out by a manual operation or an automatic operation. Furthermore, the positioning of the resin-6 dripping position implemented by the ink jet control mechanism may be carried out using an alignment mark (identification mark) on a wafer stage or using a specific point (notch) on the outside of the semiconductor wafer 2.

Next, the resin 6 is cured by carrying out heat treatment or ultraviolet (UV) treatment. If the resin 6 is, for example, a thermosetting polyimide resin, thermosetting epoxy resin, or thermosetting electrically conductive paste, the resin 6 is cured by carrying out heat treatment. The heat treatment may be carried out by, for example, transporting the semiconductor wafer 2 to a heating furnace and heating the semiconductor wafer 2 within the heating furnace. If the resin 6 is, for example, a photosensitive polyimide resin, photosensitive epoxy resin, or photosensitive electrically conductive paste, the resin 6 is cured by carrying out ultraviolet (UV) treatment.

Methods for Stacking Semiconductor Devices

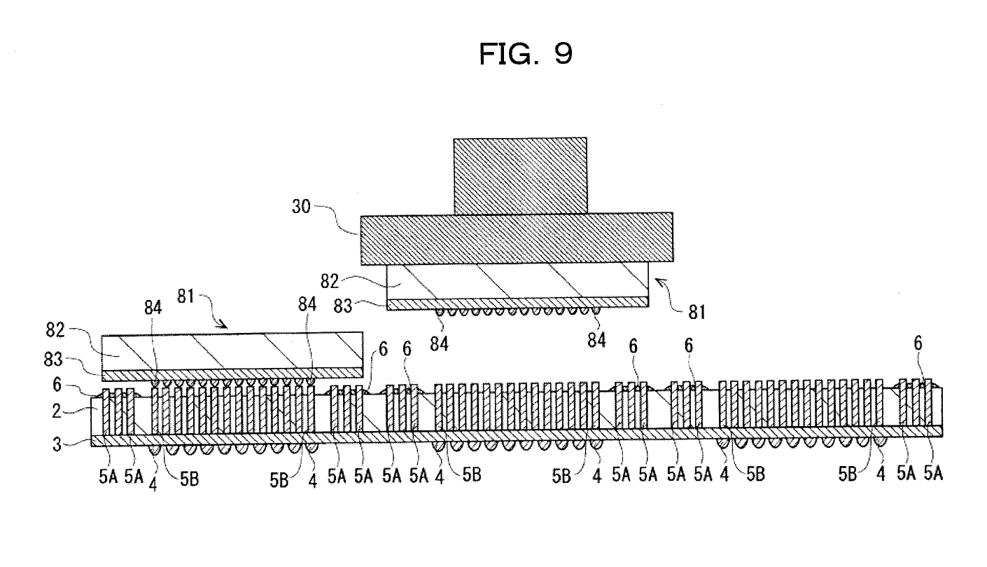

A first example of a method for stacking semiconductor devices is described with reference to FIGS. 9 to 12. An alignment mark that uses metal terminals 5A and resin 6 is formed on the rear surface of a semiconductor wafer 2. The alignment mark formed on the rear surface of the semiconductor wafer 2 is used to mount, on the rear surface of the semiconductor wafer 2, second-layer semiconductor chips (LSI chips) 81 that have been formed into individual pieces. The semiconductor chips 81 are examples of a semiconductor device. In this example, a plurality of semiconductor chips 81 are mounted on the rear surface of the semiconductor wafer 2. For example, as depicted in FIG. 9, a suction head 30 of a flip chip bonder (not depicted) suctionally adheres to a semiconductor chip 81 in a state in which a circuit-forming surface (hereafter referred to as the front surface of the semiconductor chip 81) of the semiconductor chip 81 is facing the rear surface of the semiconductor wafer 2. The semiconductor chip 81 has a semiconductor wafer 82, wiring layer 83, and connection terminals 84. The wiring layer 83 and connection terminals 84 are formed on the front surface of the semiconductor chip 81.

After the alignment mark formed on the rear surface of the semiconductor wafer 2 is identified, positioning is carried out, and the semiconductor chip 81 is mounted on the rear surface of the semiconductor wafer 2. The identification of the alignment mark formed on the rear surface of the semiconductor wafer 2 is carried out by an identification device (not depicted) which is mounted on the flip chip bonder. Metal terminals 5B contact with the connection terminals 84 of the semiconductor chip 81, and the metal terminals 5A do not contact with the surface (hereafter referred to as the rear surface of the semiconductor chip 81) of the semiconductor chip 81 on the opposite side to the circuit-forming surface.

An example of a method for identifying an alignment mark is described. The identification device mounted on the flip chip bonder irradiates the rear surface of the semiconductor wafer 2 with light and receives light reflected from the alignment mark, and thereby captures and creates an image of the alignment mark. The identification device mounted on the flip chip bonder identifies the position of the alignment mark from the image of the alignment mark. It is therefore possible to carry out positioning when the semiconductor chip 81 is to be mounted on the rear surface of the semiconductor wafer 2, by using the alignment mark formed on the rear surface of the semiconductor wafer 2.

The reflectance value of the rear surface of the semiconductor wafer 2 is closer to the reflectance value of the metal terminals 5A than the reflectance value of the resin 6. In other words, the difference between the reflectance value of the rear surface of the semiconductor wafer 2 and the reflectance value of the resin 6 is greater than the difference between the reflectance value of the rear surface of the semiconductor wafer 2 and the reflectance value of the metal terminals 5A. For this reason, an image of an alignment mark that uses the metal terminals 5A and resin 6 has a higher contrast than an image of an alignment mark that uses only the metal terminals 5A. Therefore, the identification device mounted on the flip chip bonder is able to create a high-contrast alignment mark image by capturing an image of an alignment mark that has been formed using the metal terminals 5A and resin 6.

According to embodiment 1, the alignment mark is formed on the rear surface of the semiconductor wafer 2 by forming the metal terminals 5A and resin 6 on the rear surface of the semiconductor wafer 2. Consequently, according to embodiment 1, the alignment mark may be formed on the rear surface of the semiconductor wafer 2 without forming a redistribution layer on the rear surface of the semiconductor wafer 2.

If the upper surfaces of the metal terminals 5A protruding from the rear surface of the semiconductor wafer 2 are covered with the resin 6, a level difference that is equal to the thickness of the resin 6 is generated between the metal terminals 5A and metal terminals 5B. If the semiconductor chips 81 are mounted on the rear surface of the semiconductor wafer 2 while there is a level difference between the metal terminals 5A and metal terminals 5B, the metal terminals 5B of the semiconductor wafer 2 and the connection terminals 84 of the semiconductor chips 81 may not contact with each other. Therefore, by causing the upper surfaces of the metal terminals 5A protruding from the rear surface of the semiconductor wafer 2 to be exposed from the resin 6, the generation of a level difference between the metal terminals 5A and metal terminals 5B is suppressed.

An alignment mark that uses metal terminals 5A and resin 6 may be formed on the rear surface of the semiconductor chip 81. If such an alignment mark that uses metal terminals 5A and resin 6 is formed on the rear surface of the semiconductor chip 81, the alignment mark may be used to mount a third or higher-layer semiconductor chip.

Next, the semiconductor wafer 2 and semiconductor chips 81 are transported to a heating furnace and heat treatment is carried out. The metal terminals 5B of the semiconductor wafer 2 and the connection terminals 84 of the semiconductor chips 81 are joined as a result of carrying out the heat treatment.

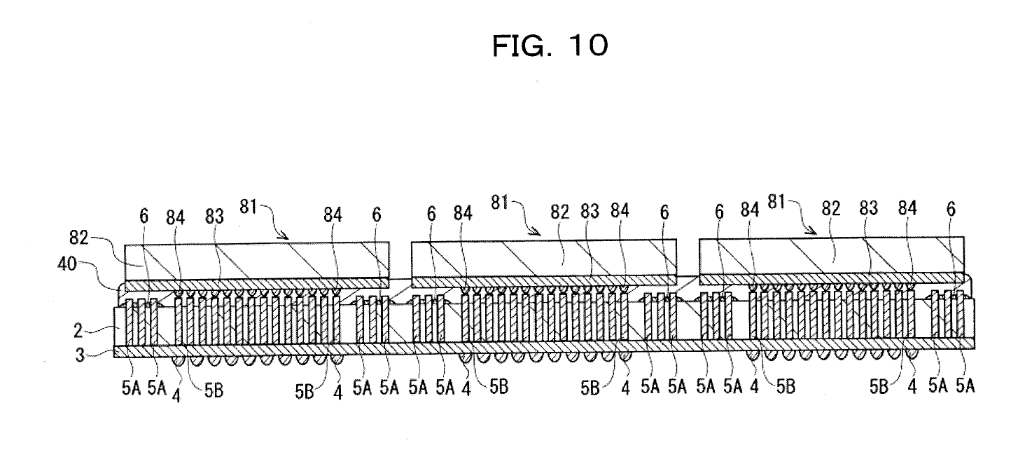

Next, as depicted in FIG. 10, a gap between the semiconductor wafer 2 and semiconductor chips 81 (the joining surfaces) is filled with an underfill material 40. The filling of the underfill material 40 is carried out, for example, by supplying the underfill material 40 from a dispenser to a gap between the semiconductor wafer 2 and semiconductor chips 81.

Next, the semiconductor wafer 2 and semiconductor chip 81 are transported to the heating furnace and heat treatment is carried out. By carrying out the heat treatment, the underfill material 40 between the semiconductor wafer 2 and semiconductor chips 81 is cured. The semiconductor chips 81 are fixed to the rear surface of the semiconductor wafer 2 by the underfill material 40.

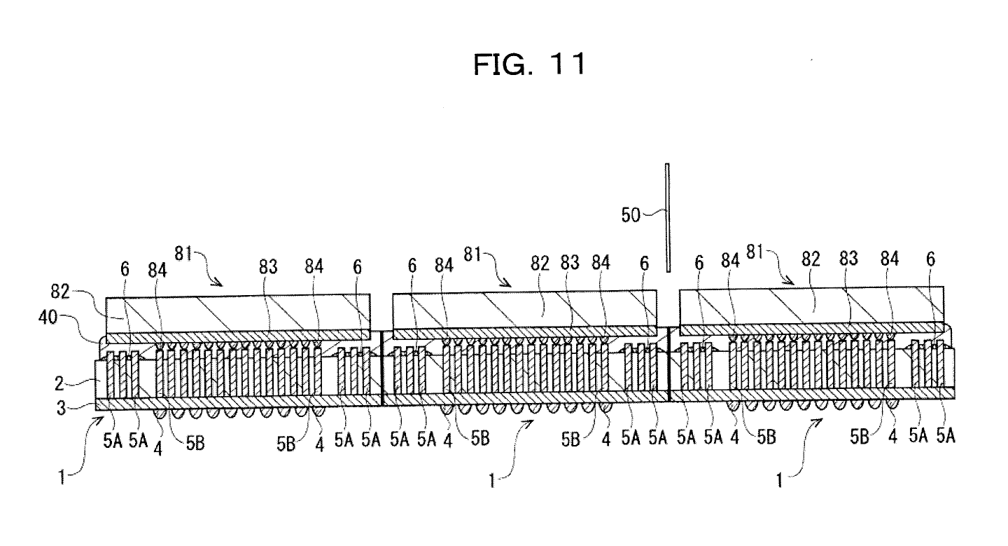

Next, a dicing blade 50 is used to dice the semiconductor wafer 2 and, as depicted in FIG. 11, semiconductor chips having a stacked configuration are thereby formed into individual pieces. The chips having a stacked configuration are hereafter referred to as stacked semiconductor chips.

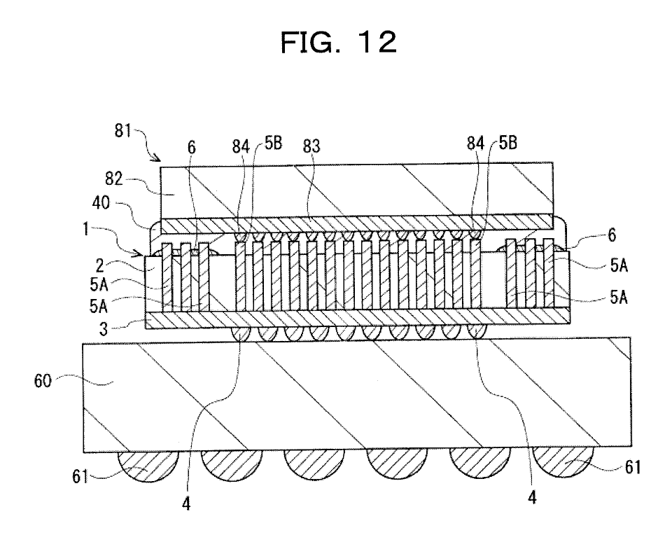

Next, the flip chip bonder is used to orientate the front surface of the first-layer semiconductor chip 1 toward an electrode-forming surface of a package substrate 60 and mount the stacked semiconductor chip on the package substrate 60, as depicted in FIG. 12. External terminals 61 are formed on the surface of the package substrate 60 on the opposite side to the electrode-forming surface. An alignment mark formed on the electrode-forming surface of the package substrate 60 is used to carry out positioning when the stacked semiconductor chip is mounted on the package substrate 60. Identification of the alignment mark formed on the electrode-forming surface of the package substrate 60 is carried out by the identification device mounted on the flip chip bonder.

Next, the stacked semiconductor chip and package substrate 60 are transported to the heating furnace and heat treatment is carried out. The connection terminals of the first-layer semiconductor chip 1 and electrodes (not depicted) of the package substrate 60 are joined as a result of carrying out the heat treatment.

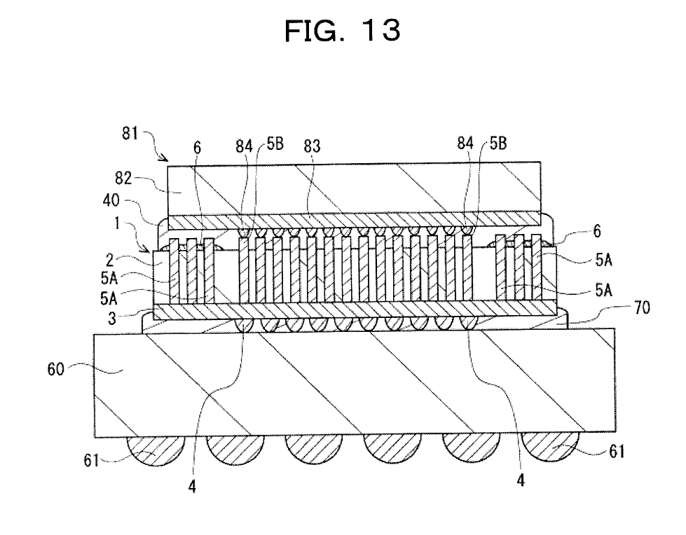

Next, as depicted in FIG. 13, a gap between the stacked semiconductor chip and package substrate 60 (the joining surfaces) is filled with an underfill material 70. The filling of the underfill material 70 is carried out, for example, by supplying the underfill material 70 from a dispenser to a gap between the stacked semiconductor chip and package substrate 60.

Next, the stacked semiconductor chip and package substrate 60 are transported to the heating furnace and heat treatment is carried out. By carrying out the heat treatment, the underfill material 70 between the stacked semiconductor chip and package substrate 60 is cured. The stacked semiconductor chip is fixed to the package substrate 60 by the underfill material 70. As a result of the stacked semiconductor chip being fixed to the package substrate 60, a semiconductor package having stacked semiconductor chips is manufactured.

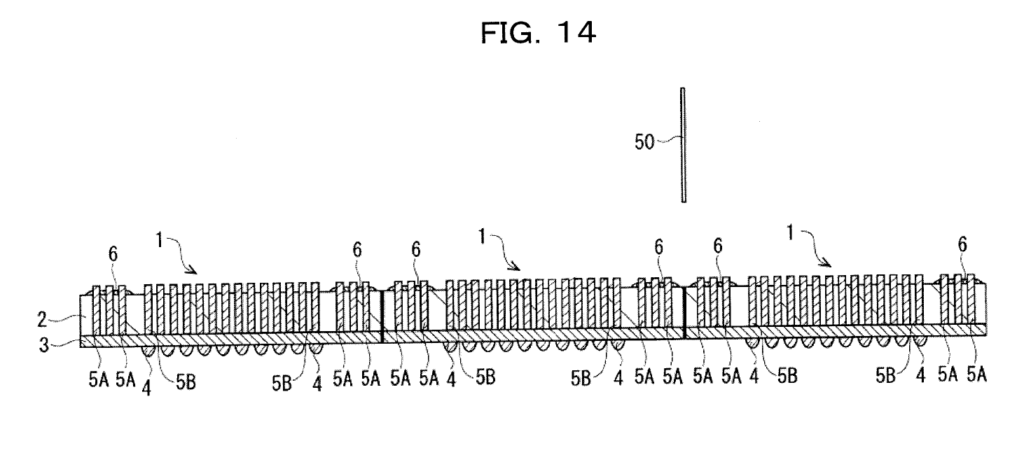

A second example of a method for stacking semiconductor devices is described with reference to FIGS. 14 to 17. A dicing blade 50 is used to dice a semiconductor wafer 2, and first-layer semiconductor chips 1 are thereby formed into individual pieces, as depicted in FIG. 14.

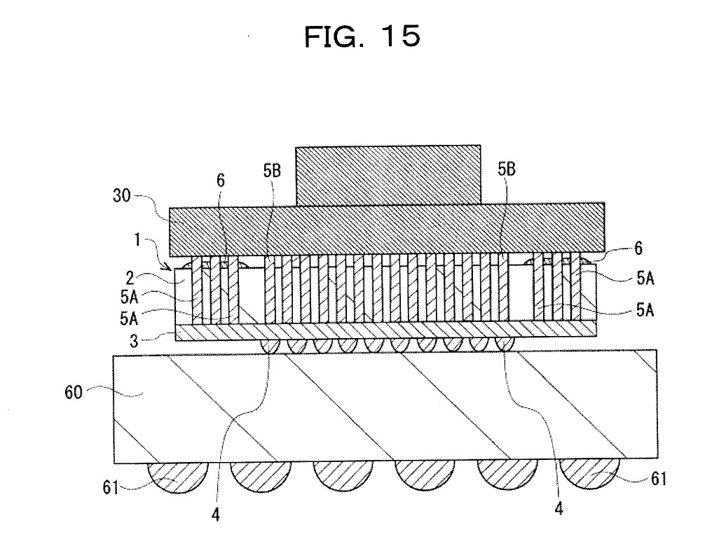

Next, the front surface of a first-layer semiconductor chip 1 is orientated toward an electrode-forming surface of a package substrate 60 and the semiconductor chip 1 is mounted on the package substrate 60. External terminals 61 are formed on the surface of the package substrate 60 on the opposite side to the electrode-forming surface. For example, as depicted in FIG. 15, a suction head 30 of a flip chip bonder suctionally adheres to the semiconductor chip 1 in a state in which the front surface of the semiconductor chip 1 is facing the electrode-forming surface of the package substrate 60.

After an alignment mark formed on the electrode-forming surface of the package substrate 60 is identified, positioning is carried out, and the semiconductor chip 1 is mounted on the electrode-forming surface of the package substrate 60. Identification of the alignment mark formed on the electrode-forming surface of the package substrate 60 is carried out by an identification device mounted on the flip chip bonder.

Next, the semiconductor chip 1 and package substrate 60 are transported to a heating furnace and heat treatment is carried out. Connection terminals 4 of the semiconductor chip 1 and electrodes (not depicted) of the package substrate 60 are joined as a result of carrying out the heat treatment.

Next, a gap between the semiconductor chip 1 and package substrate 60 (the joining surfaces) is filled with an underfill material 70. The filling of the underfill material 70 is carried out, for example, by supplying the underfill material 70 from a dispenser to a gap between the semiconductor chip 1 and package substrate 60.

Next, the semiconductor chip 1 and package substrate 60 are transported to the heating furnace and heat treatment is carried out. By carrying out the heat treatment, the underfill material 70 between the semiconductor chip 1 and package substrate 60 is cured. The semiconductor chip 1 is fixed to the package substrate 60 by the underfill material 70.

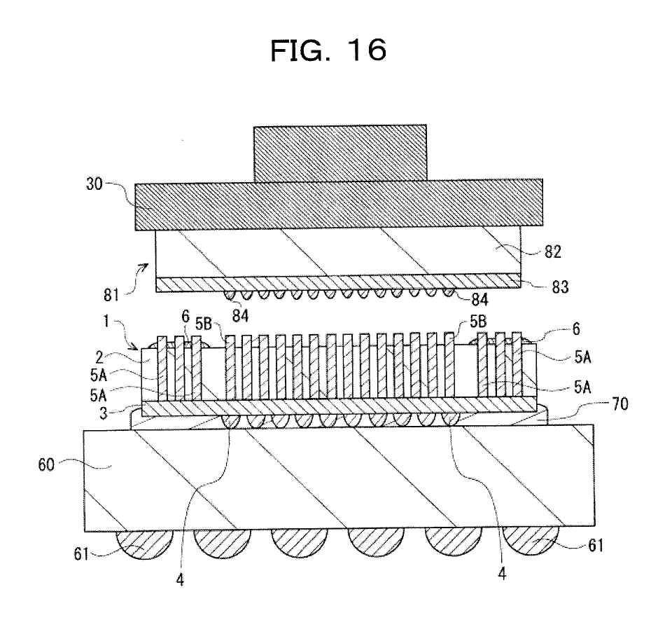

An alignment mark formed on the rear surface of the semiconductor chip 1 is used to mount, on the rear surface of the semiconductor chip 1, a second-layer semiconductor chip 81 that has been formed into an individual piece. For example, as depicted in FIG. 16, the suction head 30 of the flip chip bonder suctionally adheres to the semiconductor chip 81.

After the alignment mark formed on the rear surface of the semiconductor chip 1 is identified, positioning is carried out, and the semiconductor chip 81 is mounted on the rear surface of the semiconductor chip 1. The identification of the alignment mark formed on the rear surface of the semiconductor chip 1 is carried out by the identification device mounted on the flip chip bonder. Metal terminals 5B contact with connection terminals 84 of the semiconductor chip 81, and metal terminals 5A do not contact with the rear surface of the semiconductor chip 81.

An example of a method for identifying an alignment mark is described. The identification device mounted on the flip chip bonder irradiates the rear surface of the semiconductor chip 1 with light and receives light reflected from the alignment mark, and thereby captures and creates an image of the alignment mark. The identification device mounted on the flip chip bonder identifies the position of the alignment mark from the image of the alignment mark. It is therefore possible to carry out positioning when the semiconductor chip 81 is mounted on the rear surface of the semiconductor wafer 2, by using the alignment mark formed on the rear surface of the semiconductor chip 1.

The reflectance value of the rear surface of the semiconductor chip 1 is closer to the reflectance value of the metal terminals 5A than the reflectance value of resin 6. In other words, the difference between the reflectance value of the rear surface of the semiconductor chip 1 and the reflectance value of the resin 6 is greater than the difference between the reflectance value of the rear surface of the semiconductor chip 1 and the reflectance value of the metal terminals 5A. For this reason, an image of an alignment mark that uses the metal terminals 5A and resin 6 has a higher contrast than an image of an alignment mark that uses only the metal terminals 5A. Therefore, the identification device mounted on the flip chip bonder is able to create a high-contrast alignment mark image by capturing an image of an alignment mark that has been formed using the metal terminals 5A and resin 6. The recognition rate for the alignment mark formed on the rear surface of the semiconductor chip 1 is improved by creating a high-contrast alignment mark image.

According to embodiment 1, the alignment mark is formed on the rear surface of the semiconductor chip 1 by forming the metal terminals 5A and resin 6 on the rear surface of the semiconductor chip 1. Consequently, according to embodiment 1, the alignment mark may be formed on the rear surface of the semiconductor chip 1 without forming a redistribution layer on the rear surface of the semiconductor chip 1.

If the upper surfaces of the metal terminals 5A protruding from the rear surface of the semiconductor chip 1 are covered by the resin 6, a level difference that is equal to the thickness of the resin 6 is generated between the metal terminals 5A and metal terminals 5B. If the semiconductor chip 81 is mounted on the rear surface of the semiconductor chip 1 while there is a level difference between the metal terminals 5A and metal terminals 5B, the metal terminals 5B of the semiconductor chip 1 and connection terminals 84 of the semiconductor chip 81 may not contact with each other. Therefore, by causing the upper surfaces of the metal terminals 5A protruding from the rear surface of the semiconductor chip 1 to be exposed from the resin 6, the generation of a level difference between the metal terminals 5A and metal terminals 5B is suppressed.

In addition, an alignment mark that uses metal terminals 5A and resin 6 may be formed on the rear surface of the semiconductor chip 81. If such an alignment mark that uses metal terminals 5A and resin 6 is formed on the rear surface of the semiconductor chip 81, this alignment mark may be used to mount a third or higher-layer semiconductor chip.

Next, the semiconductor chip 1, semiconductor chip 81, and package substrate 60 are transported to the heating furnace and heat treatment is carried out. The metal terminals 5B of the semiconductor chip 1 and the connection terminals 84 of the semiconductor chip 81 are joined as a result of carrying out the heat treatment.

Next, a gap between the semiconductor chip 1 and semiconductor chip 81 (the joining surfaces) is filled with an underfill material 40. The filling of the underfill material 40 is carried out, for example, by supplying the underfill material 40 from a dispenser to a gap between the semiconductor chip 1 and semiconductor chip 81.

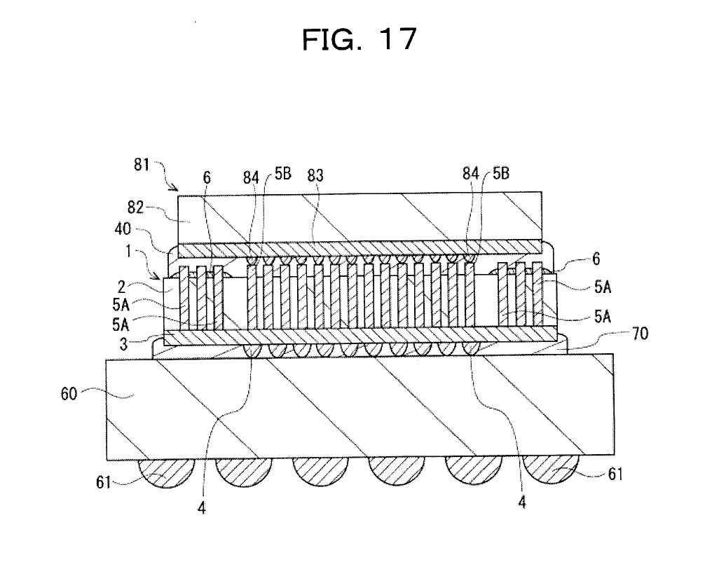

Next, the semiconductor chip 1, semiconductor chip 81, and package substrate 60 are transported to the heating furnace and heat treatment is carried out. By carrying out the heat treatment, the underfill material 40 between the semiconductor chip 1 and semiconductor chip 81 is cured. The semiconductor chip 81 is fixed to the semiconductor chip 1 by the underfill material 40. By the semiconductor chip 81 being fixed to the semiconductor chip 1, as depicted in FIG. 17, a semiconductor package having stacked semiconductor chips is manufactured.

Dimensions of a semiconductor chip 1, semiconductor wafer 2, and metal terminals 5A and 5B

The dimensions of a semiconductor chip 1, semiconductor wafer 2, and metal terminals 5A and 5B are described. However, the dimension values of the semiconductor chip 1, semiconductor wafer 2, and metal terminals 5A and 5B given below are exemplifications and, in the embodiment, other values may be employed without restriction to these values.

Diameter of the semiconductor wafer 2: 300 nm

Thickness of the semiconductor wafer 2 after the metal terminals 5A and 5B are made to protrude from the rear surface of the semiconductor wafer 2: 50 μm or more and 200 μm or less

External size of the semiconductor chip 1 after being formed into an individual piece: 10 mm² or more and 25 mm² or less

Diameter of the metal terminals 5A and 5B: φ5 μm or more and φ20 μm or less

Pitch of the metal terminals 5A and 5B: 30 μm or more and 100 μm or less

Protrusion length of the metal terminals 5A and 5B (length of the portion protruding from the rear surface of the semiconductor wafer 2): 10 μm or more and 30 μm or less

### Embodiment 2

A second embodiment (embodiment 2) of a semiconductor device and a method for manufacturing a semiconductor device according to the embodiment are described. Here, constituent elements which are the same as in embodiment 1 are denoted by the same symbols as in embodiment 1 and descriptions thereof are omitted.

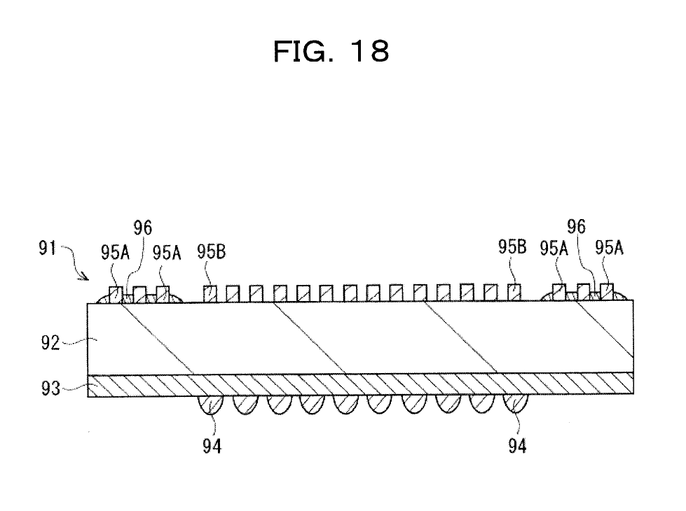

As depicted in FIG. 18, a semiconductor chip (LSI chip) 91 includes a semiconductor wafer (semiconductor substrate) 92, a wiring layer 93, connection terminals 94, metal terminals 95A and 95B, and resin 96. FIG. 18 is a cross-sectional view of the semiconductor chip 91 according to embodiment 2. The semiconductor chip 91 is an example of a semiconductor device. The semiconductor wafer 92 is, for example, a silicon wafer.

An integrated circuit is formed on one surface of the semiconductor chip 91. The integrated circuit of the semiconductor chip 91 has: an element such as a transistor which is formed on one surface of the semiconductor wafer 92 by a transistor-forming process (front end of the line; FEOL); and the wiring layer 93 which is formed by a wiring-forming process (back end of the line; BEOL). The wiring layer 93 has metal wiring, an insulation layer, and a plug, which are not depicted. The metal wiring includes a ground (GND) wire, power supply wire, and signal wire. Hereafter, the surface (circuit-forming surface) of the semiconductor chip 91 on which the integrated circuit is formed is referred to as the front surface of the semiconductor chip 91. Furthermore, the surface (circuit-forming surface) of the semiconductor wafer 92 on which the integrated circuit is formed is referred to as the front surface of the semiconductor wafer 92.

An alignment mark (identification mark) is formed by the metal terminals 95A and resin 96 on the surface of the semiconductor chip 91 on the opposite side to the circuit-forming surface (hereafter referred to as the rear surface of the semiconductor chip 91). In other words, the alignment mark formed on the rear surface of the semiconductor chip 91 includes the metal terminals 95A and resin 96. The metal terminals 95A are metal terminals used for alignment mark (identification mark), and the metal terminals 95B are metal terminals used for connection. The metal terminals 95A and 95B are formed on the rear surface of the semiconductor wafer 92. The rear surface of the semiconductor wafer 92 is the surface of the semiconductor wafer 92 on the opposite side to the circuit-forming surface.

The metal terminals 95A may be electrically connected with the metal wiring and plug of the wiring layer 93. If the metal terminals 95A are electrically connected with the ground wire of the wiring layer 93, part of the alignment mark has the same potential as ground, and noise during operation of the semiconductor chip 91 may be reduced. The metal terminals 95A may not be electrically connected with the metal wiring and plug of the wiring layer 93. Some of the plurality of metal terminals 95A may be electrically connected with the metal wiring and plug of the wiring layer 93, and some of the plurality of metal terminals 95A may not be electrically connected with the metal wiring and plug of the wiring layer 93. The metal terminals 95B are electrically connected with the metal wiring and plug of the wiring layer 93. The metal terminals 95A and 95B are, for example, copper (Cu), tungsten (W), gold (Au), or the like. The connection terminals 94 are, for example, tin-silver (SnAg) solder, gold (Ag), copper (Cu), or the like.

The resin 96 is, for example, a thermosetting polyimide resin, thermosetting epoxy resin, photosensitive polyimide resin, photosensitive epoxy resin, or an electrically conductive resin. The electrically conductive resin may be a thermosetting electrically conductive paste or a photosensitive electrically conductive paste. The photosensitive electrically conductive paste may be a photosensitive silver paste. If the resin 96 is an electrically conductive resin, the plurality of metal terminals 95A are electrically connected by the resin 96. If the metal terminals 95A are electrically connected with the ground wire of the wiring layer 93, the whole of the alignment mark has the same potential as ground, and noise during operation of the semiconductor chip 91 may be further reduced.

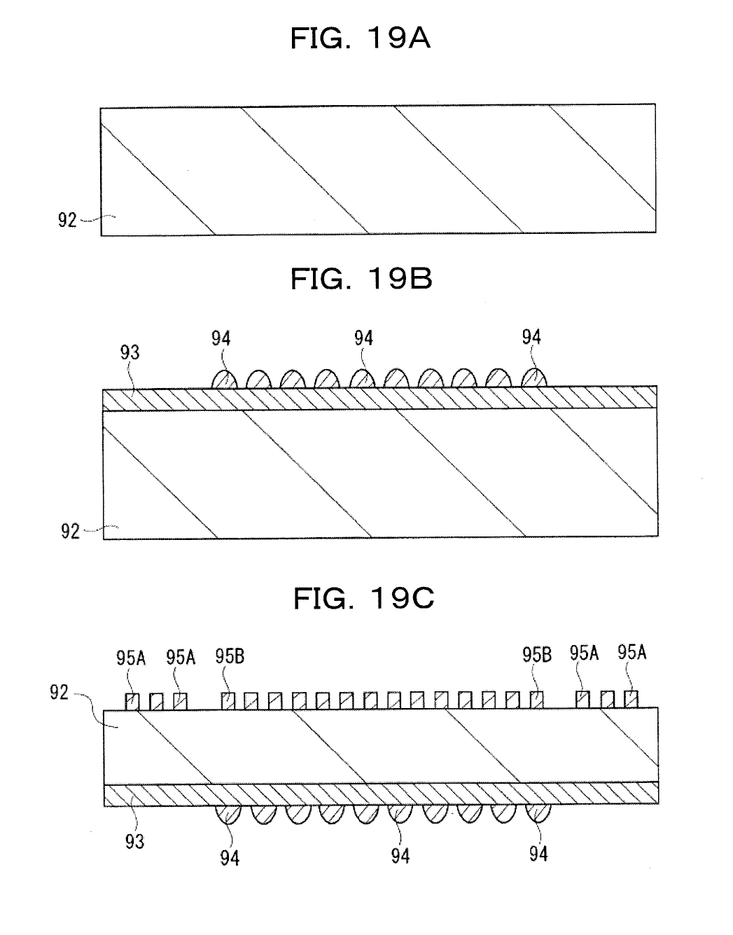

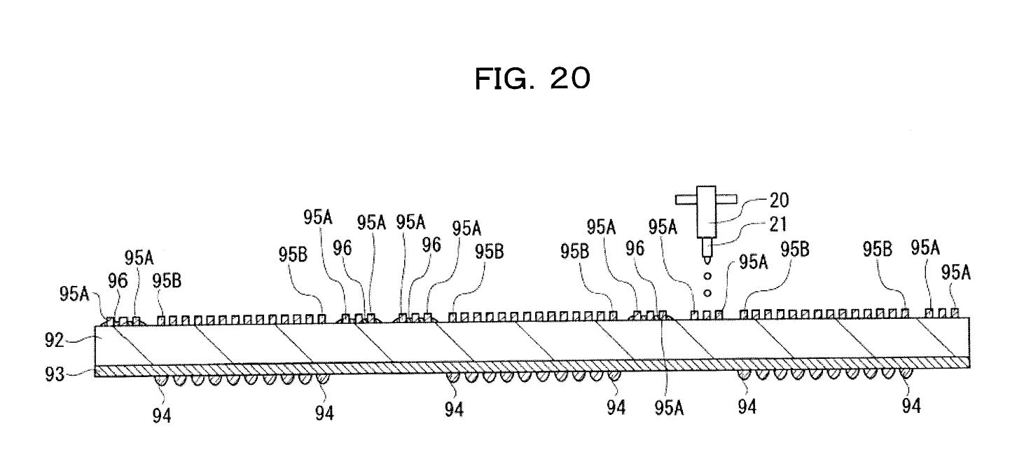

The method for manufacturing a semiconductor device according to embodiment 2 is described with reference to FIGS. 19A to 20. First, a semiconductor wafer 92 is prepared as depicted in FIG. 19A. Next, as depicted in FIG. 19B, a wiring layer 93 is formed on the front surface of the semiconductor wafer 92, and connection terminals 94 are formed on the wiring layer 93. Next, in carrying out backgrinding from the rear surface of the semiconductor wafer 92, the rear surface of the semiconductor wafer 92 is ground to thereby reduce the thickness of the semiconductor wafer 92 until the semiconductor wafer 92 reaches a certain thickness.

Next, after a resist pattern (not depicted) is formed on the rear surface of the semiconductor wafer 92 by photolithography, plating is used to form a plurality of metal terminals 95A and 95B on the rear surface of the semiconductor wafer 92, as depicted in FIG. 19C. The plurality of metal terminals 95A and 95B formed on the rear surface of the semiconductor wafer 92 protrude from the semiconductor wafer 92. The plurality of metal terminals 95A and 95B are formed in a portion of the rear surface of the semiconductor wafer 92 on which the resist pattern is not formed. For example, the metal terminals 95A and 95B are formed on the rear surface of the semiconductor wafer 92 by depositing titanium (Ti) and copper (Cu) by sputtering, and plating with copper (Cu) by electroplating. An example using copper (Cu) is described, but tungsten (W) or gold (Au) may be used instead of copper (Cu). After the metal terminals 95A and 95B have been formed on the rear surface of the semiconductor wafer 92, the resist pattern is removed by ashing.

In addition, a plurality of grooves may be formed in the rear surface of the semiconductor wafer 92 by anisotropic etching, and the plurality of metal terminals 95A and 95B may be formed in the plurality of grooves formed in the rear surface of the semiconductor wafer 92. That is, part of the individual metal terminals 95A and 95B may be embedded in the grooves formed in the rear surface of the semiconductor wafer 92.

The plurality of metal terminals 95A formed on the rear surface of the semiconductor wafer 92 are metal terminals used for an alignment mark. The metal terminals 95A used for an alignment mark form part of an alignment mark. The plurality of metal terminals 95B formed on the rear surface of the semiconductor wafer 92 are metal terminals used for connection. The metal terminals 95B used for connection are terminals which electrically connect a plurality of semiconductor chips 91 when the plurality of semiconductor chips 91 are stacked. Furthermore, the metal terminals 95B used for connection are terminals which electrically connect a semiconductor chip 91 to another semiconductor chip when the semiconductor chip 91 and the other semiconductor chip are stacked.

Next, in a state which the rear surface of the semiconductor wafer 92 is facing upward, an ink jet control mechanism is used to position an ink jet head 20 above the position where the alignment mark is to be formed on the rear surface of the semiconductor wafer 92.

Next, as depicted in FIG. 20, resin 96 is dripped (applied) from a nozzle 21 of the ink jet head 20, and the resin 96 is thereby formed in an alignment mark-forming position on the rear surface of the semiconductor wafer 92. The amount of the resin 96 that is dripped from the nozzle 21 of the ink jet head 20 is controlled to thereby form a certain amount of the resin 96 at the alignment mark-forming position on the rear surface of the semiconductor wafer 92. By controlling the amount of the resin 96 that is dripped from the nozzle 21 of the ink jet head 20, it is possible for the upper surfaces of the metal terminals 95A formed on the semiconductor wafer 92 not to be covered by the resin 96. Furthermore, by controlling the amount of the resin 96 that is dripped from the nozzle 21 of the ink jet head 20, it is possible for only part of the side surfaces of the metal terminals 95A formed on the rear surface of the semiconductor wafer 92 to be covered by the resin 96.

If the resin 96 has poor wettability with the metal terminals 95A, it is possible to inhibit the upper surfaces of the metal terminals 95A which are formed on the rear surface of the semiconductor wafer 92 from being covered by the resin 96. That is, using the resin 96 having poor wettability with the metal terminals 95A thereby makes it easy for the upper surfaces of the metal terminals 95A formed on the semiconductor wafer 92 to be exposed from the resin 96.

The metal terminals 95A are formed by using photolithography and plating. For this reason, the forming positions of the metal terminals 95A are more precise than the resin-96 dripping position implemented by the ink jet control mechanism. For example, the precision of the forming positions of the metal terminals 95A is approximately ±0.1 μm, whereas the precision of the resin-96 dripping position implemented by the ink jet control mechanism is approximately ±5 μm. Because the metal terminals 95A are provided in a position in which the alignment mark is to be formed on the rear surface of the semiconductor wafer 92, when the resin 96 is dripped on the rear surface of the semiconductor wafer 92, the resin 96 accumulates in the position in which the metal terminals 95A are formed. It is possible to form the resin 96 in a position in which the alignment mark is to be formed on the rear surface the semiconductor wafer 92, even if the precision of the resin-96 dripping position implemented by the ink jet control mechanism is low. That is, even if the resin-96 dripping position shifts slightly with respect to the position in which the alignment mark is to be formed on the rear surface of the semiconductor wafer 92. It is possible to form the resin 96 in the position in which the alignment mark is to be formed on the rear surface of the semiconductor wafer 92.

The shape of the alignment mark formed by the metal terminals 95A and resin 96 may be implemented in the shape of a cross as in embodiment 1 or may be another shape such as an “L” shape. For example, the shape of the alignment mark formed by the metal terminals 95A and resin 96 may be the same as the shape of the alignment marks each depicted in FIGS. 2 to 5. The methods for stacking semiconductor devices are the same as in embodiment 1 and the descriptions thereof are therefore omitted.

The reflectance value of the rear surface of the semiconductor chip 91 (semiconductor wafer 92) is closer to the reflectance value of the metal terminals 95A than the reflectance value of the resin 96. In other words, the difference between the reflectance value of the rear surface of the semiconductor chip 91 (semiconductor wafer 92) and the reflectance value of the resin 96 is greater than the difference between the reflectance value of the rear surface of the semiconductor chip 91 (semiconductor wafer 92) and the reflectance value of the metal terminals 95A. For this reason, an image of an alignment mark that uses the metal terminals 95A and resin 96 has a higher contrast than an image of an alignment mark that uses only the metal terminals 95A. Therefore, an identification device mounted on a flip chip bonder is able to create a high-contrast alignment mark image by capturing an image of an alignment mark that has been formed using the metal terminals 95A and resin 96. The recognition rate of the alignment mark formed on the rear surface of the semiconductor chip 91 (semiconductor wafer 92) is improved by creating a high-contrast alignment mark image.

According to embodiment 2, the alignment mark is formed on the rear surface of the semiconductor chip 91 (semiconductor wafer 92) by forming the metal terminals 95A and resin 96 on the rear surface of the semiconductor chip 91 (semiconductor wafer 92). Consequently, according to embodiment 2, the alignment mark may be formed on the rear surface of the semiconductor chip 91 (semiconductor wafer 92) without forming a redistribution layer on the rear surface of the semiconductor chip 91 (semiconductor wafer 92).

If the upper surfaces of the metal terminals 95A formed on the rear surface of the semiconductor chip 91 (semiconductor wafer 92) are covered with the resin 96, a level difference that is equal to the thickness of the resin 96 is generated between the metal terminals 95A and metal terminals 95B. If a semiconductor chip 81 is mounted on the rear surface of the semiconductor chip 91 (semiconductor wafer 92) while there is a level difference between the metal terminals 95A and metal terminals 95B, the metal terminals 95B of the semiconductor chip 91 and connection terminals 84 of the semiconductor chip 81 may not contact with each other. Therefore, by causing the upper surfaces of the metal terminals 95A formed on the rear surface of the semiconductor chip 91 (semiconductor wafer 92) to be exposed from the resin 96, the generation of a level difference between the metal terminals 95A and metal terminals 95B is suppressed.

Dimensions of a semiconductor chip 91, semiconductor wafer 92, and metal terminals 95A and 95B

The dimensions of the semiconductor chip 91, semiconductor wafer 92, and metal terminals 95A and 95B are described. However, the dimension values of the semiconductor chip 91, semiconductor wafer 92, and metal terminals 95A and 95B given below are exemplifications and, in the embodiment, other values may be employed without restriction to these values.

Diameter of the semiconductor wafer 92: 300 nm

Thickness of the semiconductor wafer 92 after backgrinding: 50 μm or more and 200 μm or less

External size of the semiconductor chip 91 after being formed into an individual piece: 10 mm² or more and 25 mm² or less

Diameter of the metal terminals 95A and 95B: φ5 μm or more and φ20 μm or less

Pitch of the metal terminals 95A and 95B: 30 μm or more and 100 μm or less

Height of the metal terminals 95A and 95B: 10 μm or more and 30 μm or less

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor device comprising:
a semiconductor substrate;
a plurality of metal terminals that are formed on a surface of the semiconductor substrate on the opposite side to a circuit-forming surface; and
a resin that is formed on the surface of the semiconductor substrate on the opposite side to the circuit-forming surface, and covers at least part of side surfaces of the metal terminals, wherein
upper surfaces of the metal terminals are exposed from the resin.

2. The semiconductor device according to claim 1, wherein
the resin has poor wettability with the metal terminals.

3. The semiconductor device according to claim 1, wherein
the resin is electrically conductive, the plurality of metal terminals are electrically connected by the resin, and the metal terminals are electrically connected to a ground wire of a circuit of the semiconductor substrate.

4. The semiconductor device according to claim 1, wherein
a semiconductor chip is formed on the surface of the semiconductor substrate on the opposite side to the circuit-forming surface, the semiconductor chip being mounted using an alignment mark including the metal terminals and the resin.

5. The semiconductor device according to claim 1, wherein
the resin is formed in a region surrounded by the plurality of metal terminals.

6. The semiconductor device according to claim 1, wherein
the metal terminals pass through the semiconductor substrate.

7. A method for manufacturing a semiconductor device, the method comprising:
forming a plurality of metal terminals on a surface of a semiconductor substrate on the opposite side to a circuit-forming surface;
forming a resin on the surface of the semiconductor substrate on the opposite side to the circuit-forming surface so as to cover at least part of side surfaces of the metal terminals; and
curing the resin, wherein
upper surfaces of the metal terminals are exposed from the resin.

8. The method for manufacturing a semiconductor device according to claim 7, wherein
the resin has poor wettability with the metal terminals.

9. The method for manufacturing a semiconductor device according to claim 7, wherein
the resin is electrically conductive, the plurality of metal terminals are electrically connected by the resin, and the metal terminals are electrically connected to a ground wire of a circuit of the semiconductor substrate.

10. The method for manufacturing a semiconductor device according to claim 7, further comprising
mounting a semiconductor chip on the surface of the semiconductor substrate on the opposite side to the circuit-forming surface, by using an alignment mark that includes the metal terminals and the resin.

11. The method for manufacturing a semiconductor device according to claim 7, wherein
the resin is formed in a region surrounded by the plurality of metal terminals.

12. The method for manufacturing a semiconductor device according to claim 7, wherein
the metal terminals pass through the semiconductor substrate.
